(19) United States
(12) Patent Application Publication
(10) Pub. No.: US 2026/0068105 A1
(43) Pub. Date: Mar. 5, 2026

(54) COOLING SYSTEM

(71) Applicant: BITMAIN TECHNOLOGIES INC, Beijing (CN)

(72) Inventors: Hangkong HU, Beijing (CN); Ketuan ZHAN, Beijing (CN); Shaoming HUANG, Beijing (CN); Hongshan ZHU, Beijing (CN); Wenkai CUI, Beijing (CN); Tianhao LI, Beijing (CN); Jian YAO, Beijing (CN); Zeqin SUN, Beijing (CN)

(21) Appl. No.: 19/317,037

(22) Filed: Sep. 2, 2025

(30) Foreign Application Priority Data
Sep. 3, 2024 (CN) 202411231233.2

(51) Int. Cl. H05K 7/20

(52) U.S. Cl. CPC H05K 7/208

(57) ABSTRACT

The present disclosure provides a cooling system connected to liquid cooling equipment. The cooling system includes: a chiller unit including a plate evaporator, a compressor, and a dry cooler; where the plate evaporator, the compressor and the dry cooler form a first medium circuit, a refrigerant medium is circulated in the first medium circuit, the plate evaporator and a cooling water source form a second medium circuit, and cooling water supplied by the cooling water source is circulated in the second medium circuit; and a control device, configured to control the connection of the first medium circuit and the disconnection of the second medium circuit, where the thermal load of the liquid cooling equipment exchanges heat with the refrigerant medium in the plate evaporator; or, configured to control the disconnection of the first medium circuit and the connection of the second medium circuit.

### CROSS-REFERENCE TO RELATED APPLICATIONS

This application claims priority to Chinese Patent Application No. 202411231233.2, filed on Sep. 3, 2024, which is hereby incorporated herein by reference in its entirety.

### TECHNICAL FIELD

The present disclosure relates to cooling technologies, and particularly to a cooling system.

### BACKGROUND

Currently, liquid cooling equipment generates thermal loads during the cooling process of electronic devices such as data centers and servers. Excessively high thermal load temperatures may impair the cooling efficiency of the liquid cooling equipment.

To further enhance the cooling efficiency of liquid cooling equipment, additional cooling can be applied to the thermal loads in the liquid cooling equipment. Typically, the type of cooling equipment is determined based on the application scenario of the liquid cooling equipment to achieve an optimal cooling solution. However, given the diverse and complex application scenarios of liquid cooling equipment, cooling equipment cannot be universally adapted to all application scenarios. In related arts, multiple types of cooling equipment are combined for operation, which leads to higher equipment costs and larger space occupation for the cooling system.

### SUMMARY

The present disclosure provides a cooling system connected to a liquid cooling equipment. The cooling system includes: a chiller unit including a plate evaporator, a compressor, and a dry cooler; where the plate evaporator, the compressor, and the dry cooler form a first medium circuit, a refrigerant medium is circulated in the first medium circuit, the plate evaporator and a cooling water source form a second medium circuit, and cooling water supplied by the cooling water source is circulated in the second medium circuit; and a control device, configured to control connection of the first medium circuit and disconnection of the second medium circuit, where thermal load of the liquid cooling equipment exchanges heat with the refrigerant medium in the plate evaporator; or, configured to control disconnection of the first medium circuit and connection of the second medium circuit, where thermal load of the liquid cooling equipment exchanges heat with the cooling water in the plate evaporator.

In some embodiments, the control device is further configured to control the connection of the first medium circuit and the disconnection of the second medium circuit when a power resource is sufficient; or, control the disconnection of the first medium circuit and the connection of the second medium circuit when the cooling water supplied by the cooling water source is sufficient.

In some embodiments, in the first medium circuit, the refrigerant medium is input into the plate evaporator to exchange the heat with the thermal load, and the heat-exchanged refrigerant medium sequentially passes through the compressor for volume compression and the dry cooler for cooling and is input into the plate evaporator again; in the second medium circuit, the cooling water from the cooling water source is input into the plate evaporator to exchange heat with the thermal load, and the heat-exchanged cooling water is output to the cooling water source.

In some embodiments, the thermal load is output to the plate evaporator from the liquid cooling equipment, and exchange heat within the plate evaporator, and the heat-exchanged thermal load is returned to the liquid cooling equipment.

In some embodiments, the chiller unit further includes a water tank, the heat-exchanged thermal load is passed through the water tank for secondary heat exchange, and is returned to the liquid cooling equipment.

In some embodiments, the chiller unit further includes: a liquid storage tank connected to the plate evaporator, and the liquid storage tank stores the refrigerant medium; the control device is further configured to control the liquid storage tank to output the refrigerant medium to the plate evaporator when the first medium circuit is connected, or, to control the liquid storage tank to stop outputting the refrigerant medium to the plate evaporator when the first medium circuit is disconnected.

In some embodiments, the chiller unit further includes: a power supply module connected to the compressor; the control device is further configured to control the power supply module to supply power to the compressor when the first medium circuit is connected.

In some embodiments, the chiller unit further includes: a water pump connected to the plate evaporator; the control device is further configured to control the water pump to pump cooling water from the cooling water source and output to the plate evaporator when the second medium circuit is connected.

In some embodiments, the thermal load is output to the dry cooler from the liquid cooling equipment and exchanges heat within the dry cooler, and the heat-exchanged thermal load is returned to the liquid cooling equipment.

In some embodiments, the cooling system further includes a cooling tower, the cooling tower includes a spray assembly, the thermal load is output to the cooling tower from the liquid cooling equipment, and exchanges heat within the cooling tower through spraying a cooling medium by the spray assembly, and the heat-exchanged thermal load is returned to the liquid cooling equipment.

In some embodiments, the control device is further configured to perform at least one of the following: controlling the thermal load to be input from the liquid cooling equipment into the plate evaporator for the heat exchange; controlling the thermal load to be input from the liquid cooling equipment into the dry cooler for the heat exchange; controlling the thermal load to be input from the liquid cooling equipment into cooling tower for the heat exchange.

The embodiments of the present disclosure offer the following beneficial effects:

In the embodiments of the present disclosure, the plate evaporator in the chiller unit and the compressor and dry cooler in the chiller unit can form a first medium circuit, and the plate evaporator in the chiller unit can form a second medium circuit with the cooling water source, enabling the plate evaporator can be in different medium circuits. By controlling the connection/disconnection states of the first and second medium circuits through the control device, the thermal load output from the liquid cooling equipment can exchange heat either with the refrigerant medium in the first medium circuit or with the cooling water in the second medium circuit. By switching between the refrigerant medium and cooling water in this process, the type of cooling source used by the chiller unit can be changed, thereby the chiller unit can adapt to different application scenarios. The cooling system in the embodiments of the present disclosure eliminates the need for additional cooling equipment, effectively reducing equipment costs and saving space.

It should be understood that the foregoing general description and the following detailed description are merely exemplary and explanatory, and should not be construed as limiting the present disclosure.

### BRIEF DESCRIPTION OF DRAWINGS

The accompanying drawings are incorporated into and form a part of this specification, illustrating embodiments consistent with the present disclosure and serving, together with the specification, to explain the principles of the present disclosure.

FIG. 1 is a schematic diagram of a first cooling structure of a cooling system provided by an embodiment of the present disclosure.

FIG. 2 is a schematic diagram of a second cooling structure of a cooling system provided by an embodiment of the present disclosure.

FIG. 3 is a schematic diagram of a third cooling structure of a cooling system provided by an embodiment of the present disclosure.

FIG. 4 is a schematic diagram of a fourth cooling structure of a cooling system provided by an embodiment of the present disclosure.

FIG. 5 is a schematic diagram of a fifth cooling structure of a cooling system provided by an embodiment of the present disclosure.

FIG. 6 is a schematic diagram of a sixth cooling structure of a cooling system provided by an embodiment of the present disclosure.

### REFERENCE NUMERALS DESCRIPTION

100, cooling system; 40, chiller unit; 41, plate evaporator; 42, compressor; 43, dry cooler; 44, control device; 54, water tank; 55, liquid storage tank; 56, first valve; 57, second valve; 58, third valve; 59, fourth valve; 80, cooling tower.

### DESCRIPTION OF EMBODIMENTS

Detailed descriptions of exemplary embodiments will be provided herein, examples of which are illustrated in the accompanying drawings. When reference is made to the drawings in the following description, unless otherwise indicated, the same numbers in different drawings represent the same or similar elements. The implementations described in the following exemplary embodiments do not represent all implementations consistent with the present disclosure. On the contrary, they are merely examples of devices consistent with certain aspects of the present disclosure, as detailed in the appended claims.

The liquid cooling equipment generates thermal loads during the cooling process of electronic devices such as data centers and servers. Excessively high thermal load temperatures may impair the cooling efficiency of the liquid cooling equipment.

To further enhance the cooling efficiency of liquid cooling equipment, additional cooling can be applied to the thermal loads in the liquid cooling equipment. Typically, the type of cooling equipment is determined based on the application scenario of the liquid cooling equipment to achieve an optimal cooling solution. However, given the diverse and complex application scenarios of liquid cooling equipment, cooling equipment cannot be universally adapted to all application scenarios. In related arts, multiple types of cooling equipment are combined for operation, which leads to higher equipment costs and larger space occupation for the cooling system.

To solve the above technical problem, an embodiment of the present disclosure provides a cooling system.

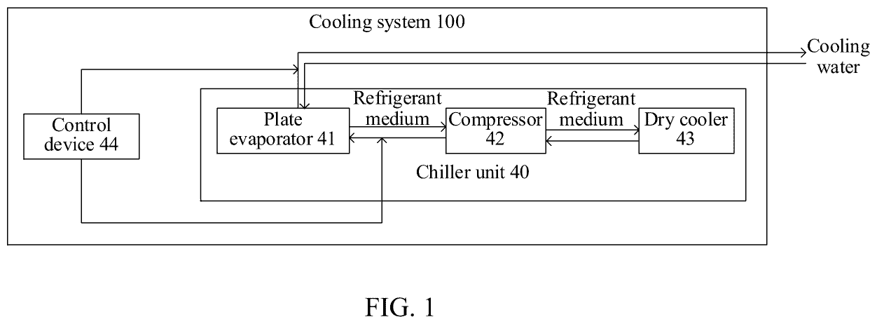

FIG. 1 is a schematic diagram of a first cooling structure of a cooling system provided by an embodiment of the present disclosure. As shown in FIG. 1, the cooling system 100 may be connected to liquid cooling equipment. The liquid cooling equipment may be configured to cool electronic devices such as data centers and servers. A coolant in the liquid cooling equipment heats up after exchanging heat with the electronic devices, thereby generating a thermal load. The liquid cooling equipment may input the heated coolant into the cooling system, the cooling system cools down the heated coolant, thereby achieving further cooling of the thermal load. The cooled coolant can be input into the liquid cooling equipment to exchange heat with the electronic devices again.

In some embodiments, the cooling system 100 may include: a chiller unit 40 and a control device 44. The chiller unit 40 may include a plate evaporator 41, a compressor 42, and a dry cooler 43. The plate evaporator 41 is connected to the compressor 42 and the dry cooler 43 to form a first medium circuit; the plate evaporator 41 is connected to a cooling water source to form a second medium circuit.

In an embodiment, the heated coolant can be understood as the thermal load output by the liquid cooling equipment, or, it can also be understood as the thermal load of the liquid cooling equipment.

In an embodiment, the coolant in the liquid cooling equipment can be ultrapure water, deionized water, etc.

In an embodiment, the liquid cooling equipment may include a water pump station, the water pump in the water pump station is used to pump the thermal load of the liquid cooling equipment out of the liquid cooling equipment.

In some embodiments, the cooling system 100 may include: a chiller unit 40 and a control device 44. The chiller unit 40 is used for heat exchange with the thermal load of the liquid cooling equipment. The control device 44 is used to control the chiller unit 40 to operate in one or more working modes.

In some embodiments, the chiller unit 40 may include a plate evaporator 41, a compressor 42, and a dry cooler 43. The plate evaporator 41, the compressor 42, and the dry cooler 43 form a first medium circuit, a refrigerant medium is circulated in the first medium circuit.

It can be understood that the first medium circuit may be a refrigeration circuit formed by the connection of the plate evaporator 41, the compressor 42, and the dry cooler 43. The refrigerant medium flows into the plate evaporator 41, sequentially passes through the compressor 42 and the dry cooler 43, and is returned to the plate evaporator 41, thus forming the first medium circuit.

In some embodiments, the connection of the plate evaporator 41, the compressor 42, and the dry cooler 43 can be achieved through pipelines. In some embodiments, parameters such as the material, shape, position, and dimensions of the pipelines can be set according to actual requirements, and the embodiments of the present disclosure do not impose any limitations in this regard.

In one embodiment, the operating principle of the plate evaporator 41 is using narrow channels between multiple plates, allowing the thermal load to flow on one side of the plates, while the refrigerant medium to flow on the other side. In this way, the thermal load and the refrigerant medium exchange heat through the plates, enabling the thermal load to transfer heat to the refrigerant medium, and the refrigerant medium absorbs the heat.

In an embodiment, the operating principle of the compressor 42 involves the reciprocating motion of a piston in a cylinder to compress the volume of the refrigerant medium. In an embodiment, when the compressor 42 compresses the low-temperature refrigerant medium, enabling the temperature of the refrigerant medium to rise.

In an embodiment, the operating principle of the dry cooler 43 is that the refrigerant medium flows in the pipelines and exchanges heat with the air outside the pipelines to lower the temperature of the refrigerant medium. In an embodiment, a fan can be provided outside the pipelines of the dry cooler 43. The fan can lower the temperature of the air outside the pipelines, thereby enhancing the cooling efficiency. In an example, the fan can be a regular fan, an air-cooling fan, etc.

In an embodiment, the plate evaporator 41 includes a first channel and a second channel. The first channel serves as the channel for the refrigerant medium within the plate evaporator 41, and at this time, the first channel can be part of the first medium circuit. The second channel serves as the channel for the thermal load of the liquid cooling equipment within the plate evaporator 41.

In an embodiment, the thermal load can be output to the second channel of the plate evaporator 41 from the liquid cooling equipment, and exchanges heat with the refrigerant medium in the first channel within the second channel. The heat-exchanged thermal load is output from the second channel and returned to the liquid cooling equipment. After absorbing heat within the first channel, the refrigerant medium continues to be circulated in the first medium circuit.

In an embodiment, the refrigerant medium can be Freon (such as chlorodifluoromethane (R22), difluoromethane (R32), tetrafluoroethane (R134a), etc.). Freon can absorb or release heat when the state changes. In an embodiment, the refrigerant medium may be circulated in the first medium circuit in a gaseous state. In some embodiments, the refrigerant medium may be circulated in the first medium circuit in a liquid state. In such cases, the compressor 42 can compress the gaseous refrigerant medium into a liquid state. The liquid refrigerant medium can absorb heat from the thermal load in the plate evaporator 41 and transition from a liquid to a gaseous state.

In an embodiment, when the refrigerant medium is circulated in the first medium circuit in a gaseous state, the plate evaporator 41 can use the gaseous refrigerant medium to exchange heat with the thermal load, thereby facilitating heat exchange between the gas and liquid phases.

In an embodiment, the chiller unit 40 can be an air-cooled chiller. The components of the air-cooled chiller, including the plate evaporator 41, compressor 42, dry cooler 43, and refrigerant medium, work in coordination to achieve an effective cooling effect.

In some embodiments, in the first medium circuit, the refrigerant medium is input into the plate evaporator 41 to exchange heat with the thermal load. The heat-exchanged the refrigerant medium sequentially passes through the compressor 42 for volume compression and the dry cooler 43 for cooling, and is input into the plate evaporator 41 again.

In an embodiment, after exchanging heat with the thermal load in the plate evaporator 41, the refrigerant medium can absorb heat from the thermal load, and the temperature is increased. The refrigerant medium with the increased temperature is input into the compressor 42, the compressor 42 compresses it to reduce the volume of the refrigerant medium, increase its pressure, and further raise its temperature to form a high-temperature and high-pressure refrigerant medium. This high-temperature and high-pressure refrigerant medium first is cooled in the dry cooler 43. The cooled refrigerant medium passes through a pressure relief valve in the dry cooler 43 to reduce pressure, thereby forming a low-temperature and low-pressure refrigerant medium. This low-temperature and low-pressure refrigerant medium is input into the plate evaporator 41 to exchange heat with the thermal load again.

In some embodiments, the chiller unit 40 further includes a power supply module connected to the compressor 42. It can be understood that the power supply module can supply power to the compressor 42.

In some embodiments, the plate evaporator 41 forms a second medium circuit with a cooling water source, and cooling water supplied by the cooling water source is circulated in the second medium circuit.

In an embodiment, the second medium circuit can serve as a refrigeration circuit for the cooling water. In an embodiment, the cooling water flows into the plate evaporator 41, then flows from the plate evaporator 41 into a cooling water source, and the cooling water in the cooling water source flows into the plate evaporator 41 again, thereby forming the second medium circuit.

In some embodiments, the connection between the plate evaporator 41 and the cooling water source can be achieved by pipelines. In an embodiment, parameters such as the material, shape, position, and length of the pipelines can be set according to actual requirements, and present disclosure does not impose any limitations in this regard.

In an embodiment, the first channel in the plate evaporator 41 can also serve as the channel for cooling water in the plate evaporator 41. At this time, the first channel can be a part of the second medium circuit. The second channel serves as the channel for the thermal load of the liquid cooling equipment in the plate evaporator 41.

In an embodiment, the thermal load can be output to the second channel of the plate evaporator 41 from the liquid cooling equipment, and exchanges heat with the cooling water within the first channel. The heat-exchanged thermal load is output from the second channel and returned to the liquid cooling equipment. After absorbing heat in the first channel, the cooling water continues to be circulated in the second medium circuit.

In an embodiment, the cooling water source can be a natural water source, such as lakes, oceans, etc.

In an embodiment, the chiller unit 40 further includes a water pump connected to the plate evaporator 41. The water pump is used for pumping cooling water from the cooling water source and output to the plate evaporator 41.

In an embodiment, when the cooling water is circulated in the second medium circuit, the plate evaporator 41 can use the cooling water to exchange heat with the thermal load, thereby forming liquid-to-liquid heat exchange.

In some embodiments, after the thermal load is input to the plate evaporator 41, the control device 44 can control the connection/disconnection of the first medium circuit and the second medium circuit to enable the thermal load to be cooled using different heat exchange methods. In an embodiment, the control device 44 can control the connection of the first medium circuit and the disconnection of the second medium circuit. At this time, the thermal load of the liquid cooling equipment undergoes gas-to-liquid heat exchange with the refrigerant medium circulated in the first medium circuit within the plate evaporator 41. In an embodiment, the control device 44 can also control the disconnection of the first medium circuit and the connection of the second medium circuit. At this time, the thermal load of the liquid cooling equipment undergoes liquid-to-liquid heat exchange with the cooling water in the second medium circuit within the plate evaporator 41.

In the embodiments of the present disclosure, the control device 44 controls one of the first medium circuit and the second medium circuit to be connected while the other is disconnected to enable the thermal load of the liquid cooling equipment to exchange heat with different cooling media (such as refrigerant medium or cooling water) within the plate evaporator 41. As a result, the type of the cooling medium used in the plate evaporator 41 can be changed, allowing the plate evaporator 41 to provide multiple cooling methods to suit different application scenarios.

In an embodiment, the control device 44 may be a combination of software and/or hardware designed to achieve predetermined functions. In some embodiments, the control device 44 may be a processor in the form of a hardware-decoded processor, programmed to execute control over the first medium circuit and the second medium circuit. For instance, the processor in the form of a hardware-decoded processor may utilize one or more application specific integrated circuits (ASIC), digital signal processors (DSP), programmable logic devices (PLD), complex programmable logic devices (CPLD), field-programmable gate arrays (FPGA), or other electronic components. The present disclosure does not impose specific limitations in this regard.

In an embodiment, valves may be provided on the first medium circuit and the second medium circuit. The control device 44 can control the opening and closing of these valves to control the connection/disconnection of the first medium circuit and the second medium circuit.

In an embodiment, the valves in the first medium circuit and the second medium circuit can be one-way valves. The control device 44 can separately control the opening and closing of the one-way valves on the first medium circuit and/or the opening and closing of the one-way valves on the second medium circuit to control the connection/disconnection of the first medium circuit and the second medium circuit.

In an embodiment, the valves on the first medium circuit and the second medium circuit can be multi-port valves, with different ports of the multi-port valves connected to the first medium circuit and the second medium circuit respectively. The control device 44 can control the opening and closing of different ports of the multi-port valves to control the connection/disconnection of the first medium circuit and the second medium circuit.

In some embodiments, the valves on the first medium circuit and the second medium circuit can be solenoid valves. The control device 44 adjusts the flow rates of the refrigerant medium in the first medium circuit and/or the cooling water in the second medium circuit by controlling the opening degrees of the solenoid valves, thereby adjusting the refrigeration efficiency.

In an embodiment, when the first medium circuit is connected, the control device 44 controls the power supply module to supply power to the compressor 42, enabling the refrigerant medium to be circulated in the first medium circuit.

In an embodiment, when the second medium circuit is connected, the control device 44 controls the water pump to pump cooling water from the cooling water source and output to the plate evaporator 41, enabling the cooling water to be circulated in the second medium circuit.

In some embodiments, when a power resource is sufficient, the control device 44 controls connection of the first medium circuit and disconnection of the second medium circuit. In this way, the refrigerant medium completes heat exchange with the thermal load in the plate evaporator 41, reducing the demand for natural water resources. In some embodiments, when the cooling water supplied by the cooling water source is sufficient, the control device 44 controls disconnection of the first medium circuit and connection of the second medium circuit. In this way, the cooling water completes heat exchange with the thermal load in the plate evaporator 41, minimizing the demand for power resources.

In an embodiment, when a power resource is sufficient, the control device 44 controls connection of the first medium circuit and disconnection of the second medium circuit, using compression refrigeration of compressor 42 to cool the refrigerant medium, and the cooled refrigerant medium is circulated in the plate evaporator 41 to remove heat from the thermal load, completing heat exchange with the thermal load. In an embodiment, when the cooling water supplied by the cooling water source is sufficient, the control device 44 controls connection of the second medium circuit and disconnection of the first medium circuit, and the cooling water is circulated in the plate evaporator 41 to remove heat from the thermal load, completing heat exchange with the thermal load.

In an embodiment, the cooling system 100 may include a detection assembly, the detection assembly is connected to the plate evaporator 41, and is configured to detect the water level of the cooling water source. Under this circumstance, the control device 44 can further control, according to the water level of the cooling water source, the connection/disconnection of the first medium circuit and the connection/disconnection of the second medium circuit.

In an embodiment, when the water level of the cooling water source falls below a threshold, the control device 44 controls the first medium circuit to be connected and the second medium circuit to be disconnected, enabling the power resources to cool the thermal load of the liquid cooling equipment, thereby enhancing cooling efficiency. In an embodiment, when the water level of the cooling water source rises above the threshold, the control device 44 controls the second medium circuit to be connected and the first medium circuit to be disconnected, enabling the natural water resources to cool the thermal load of the liquid cooling equipment, thereby achieving cost savings.

In some embodiments, the chiller unit 40 further includes a water tank, and the water tank stores cooling water. The heat-exchanged thermal load in the plate evaporator 41 can be input into the water tank for secondary heat exchange, after the secondary heat exchange, the thermal load can be returned to the liquid cooling equipment.

In an embodiment, at the end of the plate evaporator 41 where the heat-exchanged thermal load is output, a water tank can be connected. The water tank can perform secondary heat exchange on the heat-exchanged thermal load, which can further improve the cooling efficiency of the cooling system. Additionally, the water tank can also buffer the heat-exchanged thermal load, evening out the temperature of thermal load, so that the heat-exchanged thermal load can be input into the liquid cooling equipment at an appropriate temperature.

In an embodiment, the chiller unit 40 further includes a liquid storage tank connected to the plate evaporator 41. The liquid storage tank stores a refrigerant medium. When the first medium circuit is connected, the control device 44 can control the liquid storage tank to output the refrigerant medium to the plate evaporator 41. When the first medium circuit is disconnected, the control device 44 can control the liquid storage tank to stop outputting the refrigerant medium to the plate evaporator 41.

In an embodiment, a liquid storage tank can be connected to an input end of the plate evaporator 41 for the refrigerant medium. The liquid storage tank can store a refrigerant medium, for example, a liquid refrigerant medium. In an embodiment, when the first medium circuit is connected, the control device 44 controls the liquid storage tank to output the refrigerant medium to the plate evaporator 41 to exchange heat between the refrigerant medium and the thermal load of the liquid cooling equipment. In an embodiment, when the first medium circuit is disconnected, the control device 44 controls the liquid storage tank to stop outputting the refrigerant medium to the plate evaporator 41, enabling the cooling water to be input into the plate evaporator 41 for exchanging heat between the cooling water and the thermal load of the liquid cooling equipment.

In embodiments of the present disclosure, the plate evaporator, the compressor and the dry cooler in the chiller unit may form a first medium circuit, and the plate evaporator in a chiller unit can form a second medium circuit with a cooling water source, enabling the plate evaporator can be in different medium circuits. By controlling connection/disconnection states of the first and second medium circuits through a control device, a thermal load output from liquid cooling equipment can exchange heat either with a refrigerant medium in the first medium circuit or with cooling water in the second medium circuit. By switching between the refrigerant medium and cooling water in this process, the type of cooling source used by the chiller unit can be changed, thereby the chiller unit can adapt to different application scenarios. The cooling system in the embodiments of the present disclosure eliminates the need for additional cooling equipment, effectively reducing equipment costs and saving space.

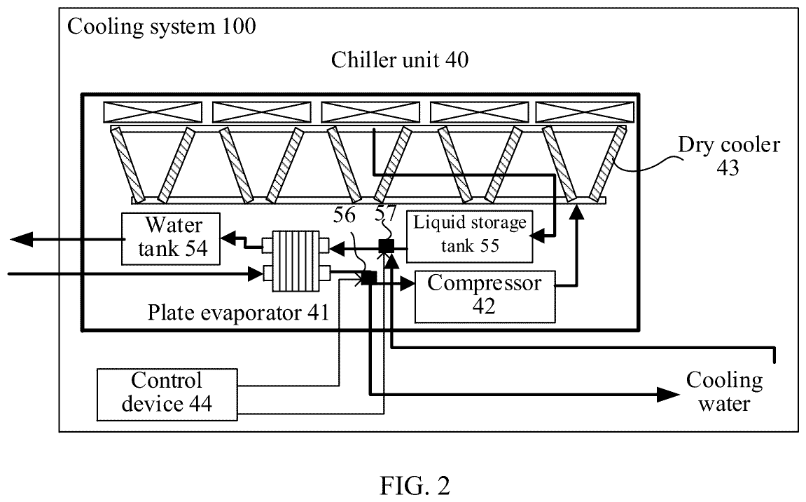

FIG. 2 is a schematic diagram of a second cooling structure of a cooling system provided by an embodiment of the present disclosure. Referring to FIG. 2, the cooling system 100 may include a chiller unit 40. The liquid cooling equipment may include a heat dissipation device, a power distribution cabinet, and a water pump station. Among them, the power distribution cabinet can supply power to the heat dissipation device. Under the action of water pump in the water pump station, the heat dissipation device enables the coolant to exchange heat with servers. The temperature of the heat-exchanged coolant is risen, forming a thermal load. Additionally, the liquid cooling equipment can be connected to the plate evaporator 41 in the chiller unit 40 via pipelines.

In an embodiment, the water pump in the water pump station can pump the thermal load of the liquid cooling equipment into a first input port of the plate evaporator 41 in the chiller unit 40 through an output port of the liquid cooling equipment. After exchanging heat within the plate evaporator 41, the thermal load can be output to the water tank 54 from the first output port of the plate evaporator 41. After the water tank performs secondary heat exchange on the heat-exchanged thermal load, the heat-exchanged thermal load can be input into the liquid cooling equipment through the input port of the liquid cooling equipment again.

In an embodiment, the chiller unit 40 may include: a plate evaporator 41, a compressor 42, a dry cooler 43, a liquid storage tank 55, a water tank 54, a water pump, a first valve 56, and a second valve 57. A second output port of the plate evaporator 41 is connected to a first port of the first valve 56, the first port of the first valve 56 is connected to a second port of the first valve 56, and the second port of the first valve 56 is connected to the compressor 42, the compressor 42 is connected to the dry cooler 43, the dry cooler 43 is connected to the liquid storage tank 55, the liquid storage tank 55 is connected to a first port of the second valve 57, the first port of the second valve 57 is connected to a second port of the second valve 57, and the second port of the second valve 57 is connected to the second input port of the plate evaporator 41, forming the first medium circuit. The second output port of the plate evaporator 41 is connected to the first port of the first valve 56, the first port of the first valve 56 is connected to a third port of the first valve 56, and the third port of the first valve 56 is connected to a cooling water source, the cooling water source is connected to the third port of the second valve 57, the third port of the second valve 57 is connected to the second port of the second valve 57, and the second port of the second valve 57 is connected to the second input port of the plate evaporator 41, forming the second medium circuit.

In an embodiment, the control device 44 controls the first port of the first valve 56 to be connected with the second port of the first valve 56 while controls the first port of the first valve 56 to be disconnected with the third port of the first valve 56, and controls the first port of the second valve 57 to be connected with the second port of the second valve 57 while controls the second port of the second valve 57 to be disconnected with the third port of the second valve 57, enabling the connection of the first medium circuit and the disconnection of the second medium circuit. The control device 44 controls the liquid storage tank 55 to output the refrigerant medium to the plate evaporator 41 and the power supply module to supply power to the compressor 42. The refrigerant medium enters the plate evaporator 41 through the second input port of the plate evaporator 41, after exchanging heat with the thermal load of the liquid cooling equipment, the temperature is risen, and subsequently passes through the second output port of the plate evaporator 41 to be input into the compressor 42. The compressor 42 compresses the refrigerant medium, forming a high-temperature and high-pressure refrigerant medium; then the high-temperature and high-pressure refrigerant medium is cooled in the dry cooler 43. After being depressurized, the cooled refrigerant medium become a low-temperature refrigerant medium, which can be input into the plate evaporator 41 again to repeat the aforementioned process in a cyclic manner.

In an embodiment, the control device 44 controls the first port of the first valve 56 to be disconnected with the second port of the first valve 56 while controls the first port of the first valve 56 to be connect with the third port of the first valve 56, and controls the first port of the second valve 57 to be disconnected with the second port of the second valve 57 while controls the second port of the second valve 57 to be connected with the third port of the second valve 57, enabling the connection of the second medium circuit and the disconnection of the first medium circuit. The control device 44 controls the water pump to output cooling water to the plate evaporator 41 from the cooling water source. The cooling water is input into the plate evaporator 41 through the second input port of the plate evaporator 41, after exchanging heat with the thermal load of the liquid cooling equipment, the temperature is risen, and subsequently is input into the cooling water source through the second output port of the plate evaporator 41. The cooling water in the cooling water source can be input into the plate evaporator 41 again to repeat the aforementioned process in a cyclic manner.

In the embodiments of the present disclosure, the plate evaporator 41 within the chiller unit 40 can achieve cooling under different application scenarios, eliminating the need for additional cooling equipment in the cooling system, thereby effectively reducing equipment costs and saving space.

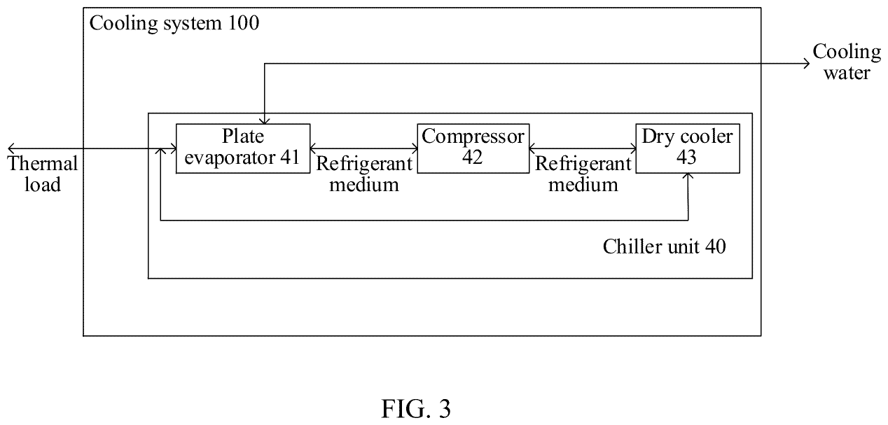

FIG. 3 is a schematic diagram of a third cooling structure of a cooling system provided by an embodiment of the present disclosure. Referring to FIG. 3, the thermal load of the liquid cooling equipment can also be output to the dry cooler 43 of the chiller unit 40 from the liquid cooling equipment, and exchange heat within the dry cooler 43. The heat-exchanged thermal load is returned to the liquid cooling equipment.

It can be understood that the dry cooler 43 includes dry cooling pipelines, the thermal load of the liquid cooling equipment can flow in dry cooling pipelines and exchange heat with the air outside the dry cooling pipelines, thereby achieving cooling of the thermal load.

In some embodiments, the control device 44 may control the thermal load to be input from the liquid cooling equipment into the dry cooler 43 for the heat exchange. In some embodiments, the control device 44 may control the thermal load to be input from the liquid cooling equipment into the plate evaporator 41 for the heat exchange. In some embodiments, the control device 44 may control the thermal load to be input from the liquid cooling equipment into the dry cooler 43 for the heat exchange, meanwhile control the thermal load to be input from the liquid cooling equipment into the plate evaporator 41 for the heat exchange.

In an embodiment, valves can be provided between the liquid cooling equipment and the chiller unit 40. The control device 44 can control whether the thermal load is input to the dry cooler 43 for heat exchange by opening or closing the valves. The control device 44 can also control whether the thermal load is input to the plate evaporator 41 for heat exchange by opening or closing the valves.

In an embodiment, the valves between the liquid cooling equipment and the chiller unit 40 can be one-way valves. The control device 44 can separately control the opening and closing of the one-way valve between the liquid cooling equipment and the dry cooler 43 and/or the opening and closing of the one-way valve between the liquid cooling equipment and the plate evaporator 41, to control the connection/disconnection between the liquid cooling equipment and the dry cooler 43, as well as the connection/disconnection between the liquid cooling equipment and the plate evaporator 41.

In some embodiments, the valves between the liquid cooling equipment and the chiller unit 40 can be multi-port valves, with different ports of the multi-port valve connected to the dry cooler 43 and the plate evaporator 41, respectively. The control device 44 can control the opening and closing of different ports on the multi-port valve to control the connection/disconnection between the liquid cooling equipment and the dry cooler 43, as well as the connection/disconnection between the liquid cooling equipment and the plate evaporator 41.

In some embodiments, the valves between the liquid cooling equipment and the chiller unit 40 can be solenoid valves. The control device 44 can adjust the flow rate of the thermal load entering the dry cooler 43 by controlling the opening degree of the solenoid valves, thereby adjusting the cooling efficiency; or, can adjust the flow rate of the thermal load entering the plate evaporator 41 by controlling the opening degree of the solenoid valves, thereby adjusting the cooling efficiency.

In an embodiment, the dry cooler 43 may include a fan, and the cooling efficiency of the dry cooler 43 can be adjusted by controlling the operating frequency of the fan.

It can be understood that in application scenarios where the temperature is not excessively high but water is relatively scarce, the dry cooler 43 can be used for heat exchange. The cooling system 100 can use the dry cooler 43 for heat exchange with the thermal load in water-scarce environments, use cooling water in the plate evaporator 41 for heat exchange with the thermal load in water-abundant environments, and use the refrigerant medium in the plate evaporator 41 for heat exchange with the thermal load in environments rich in power resources, enabling the chiller unit 40 to be applicable in various application scenarios, thereby effectively reducing equipment costs and saving space.

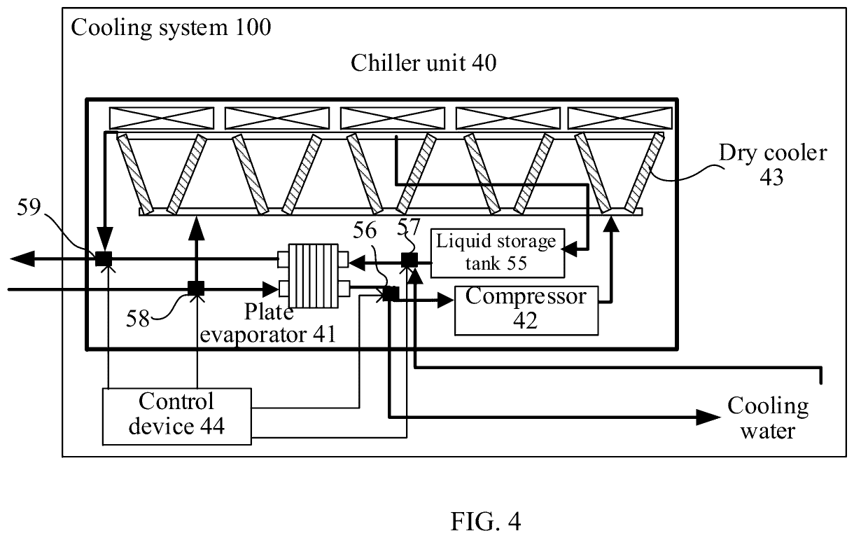

FIG. 4 is a schematic diagram of a fourth cooling structure of a cooling system provided by an embodiment of the present disclosure. Referring to FIG. 4, the liquid cooling equipment can be connected via pipelines to the plate evaporator 41 of the chiller unit 40 and also can be connected via pipelines to the dry cooler 43 of the chiller unit 40.

In an embodiment, the water pump can input the thermal load of the liquid cooling equipment to the dry cooler 43 of the chiller unit 40 through the output port of the liquid cooling equipment. After exchanging heat within the dry cooler 43, the thermal load can be output to the input port of the liquid cooling equipment from the dry cooler 43 to be input into the liquid cooling system again.

In an embodiment, the chiller unit 40 may further include: a third valve 58 and a fourth valve 59, the output port of the liquid cooling equipment is connected to the first port of the third valve 58, and the first port of the third valve 58 is connected to the second port of the third valve 58. The second port of the third valve 58 is connected to the first input port of the plate evaporator 41, the first output port of the plate evaporator 41 is connected to the first port of the fourth valve 59, and the first port of the fourth valve 59 is connected to the second port of the fourth valve 59, the second port of the fourth valve 59 is connected to the input port of the liquid cooling equipment, forming a circuit between the liquid cooling equipment and the plate evaporator 41. The output port of the liquid cooling equipment is connected to the first port of the third valve 58, and the first port of the third valve 58 is connected to the third port of the third valve 58, the third port of the third valve 58 is connected to the dry cooler 43, and the dry cooler 43 is connected to the third port of the fourth valve 59, the third port of the fourth valve 59 is connected to the second port of the fourth valve 59, the second port of the fourth valve 59 is connected to the input port of the liquid cooling equipment, forming a circuit between the liquid cooling equipment and the dry cooler 43.

In an embodiment, the control device 44 controls the first port of the third valve 58 to be connected to the second port of the third valve 58 while controls the first port of the third valve 58 to be disconnected with the third port of the third valve 58, and controls the first port of the fourth valve 59 to be connected to the second port of the fourth valve 59 while controls the third port of the fourth valve 59 to be disconnected with the second port of the second valve 57, enabling the thermal load of the liquid cooling equipment to be input into the plate evaporator 41 for heat exchange. The thermal load of the liquid cooling equipment is input into the plate evaporator 41 through the output port of the liquid cooling equipment and the first input port of the plate evaporator 41. After exchanging heat within the plate evaporator 41, the thermal load can be output to the water tank 54 from the first output port of the plate evaporator 41, and then exit the water tank 54 to be input into the liquid cooling equipment again through the input port of the liquid cooling equipment from the water tank 54.

It can be understood that when the control device 44 inputs the thermal load of the liquid cooling equipment into the plate evaporator 41 for heat exchange, it can also control the connection of either the first medium circuit or the second medium circuit, enabling the thermal load to exchange heat either with the refrigerant medium or with the cooling water in the plate evaporator 41.

In an embodiment, the control device 44 controls the first port of the third valve 58 to be disconnected with the second port of the third valve 58 while controls the first port of the third valve 58 to be connected with the third port of the third valve 58, and controls the first port of the fourth valve 59 to be disconnected with the second port of the fourth valve 59 while controls the third port of the fourth valve 59 to be connected with the second port of the second valve 57, enabling the thermal load of the liquid cooling equipment to be input into the dry cooler 43 for heat exchange. The thermal load is input into the dry cooler 43 through the output port of the liquid cooling equipment. After exchanging heat with the external air within the dry cooler 43, the thermal load can exit the dry cooler 43 and be input into the liquid cooling equipment again through the input port of the liquid cooling equipment.

It should be noted that when the control device 44 controls the thermal load of the liquid cooling equipment to be simultaneously input into both the plate evaporator 41 and the dry cooler 43 for heat exchange, the control device 44 should also control the first port of the first valve 56 to be disconnected with the second port of the first valve 56 while control the first port of the first valve 56 to be connected with the third port of the first valve 56, and control the first port of the second valve 57 to be disconnected with the second port of the second valve 57 while control the second port of the second valve 57 to be connected with the third port of the second valve 57, enabling the connection of the second medium circuit and the disconnection of the first medium circuit.

In the embodiments of the present disclosure, the dry cooler 43 in the chiller unit 40 can achieve cooling under different application scenarios, thereby eliminating the need to add additional cooling equipment to the cooling system. This effectively reduces equipment costs and saves space.

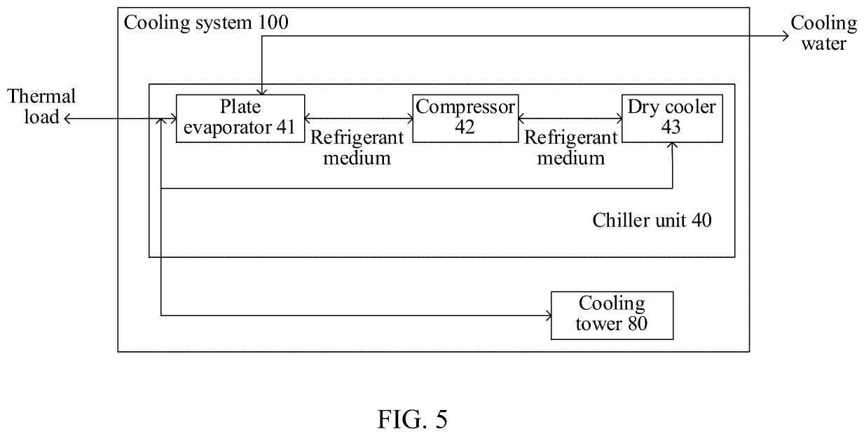

FIG. 5 is a schematic diagram of a fifth cooling structure of a cooling system provided by an embodiment of the present disclosure. Referring to FIG. 5, the cooling system further includes a cooling tower 80, the cooling tower 80 includes a spray assembly. The thermal load of the liquid cooling equipment can also be output to the cooling tower 80 from the liquid cooling equipment, and exchange heat within the cooling tower through spraying a cooling medium by the spray assembly. The heat-exchanged thermal load is returned to the liquid cooling equipment.

It can be understood that the cooling tower 80 includes cooling pipelines and a spray assembly. The spray assembly sprays a cooling medium onto the cooling pipelines, enabling heat exchange between the thermal load in the cooling pipelines and the cooling medium outside the pipelines, thereby achieving cooling of the thermal load.

In some embodiments, the cooling tower 80 may be a closed-type cooling tower 80.

In an embodiment, the cooling medium can be deionized water, ultrapure water, etc.

In some embodiments, the control device 44 can control the thermal load to be input from the liquid cooling equipment into the cooling tower 80 for heat exchange. In some embodiments, while controlling the thermal load to be input from the liquid cooling equipment into the cooling tower 80 for heat exchange, the control device 44 can also simultaneously control the thermal load to be input from the liquid cooling equipment into the plate evaporator 41 for heat exchange and/or control the thermal load to be input from the liquid cooling equipment into the dry cooler 43 for heat exchange.

In an embodiment, a valve can be provided between the liquid cooling equipment and the cooling tower 80. The control device 44 can control whether the thermal load is input into the cooling tower 80 for heat exchange by controlling the opening and closing of the valve.

In an embodiment, the valve between the liquid cooling equipment and the cooling tower 80 can be a one-way valve. The control device 44 can control the opening and closing of the one-way valve between the liquid cooling equipment and the cooling tower 80 to control the connection/disconnection between the liquid cooling equipment and the dry cooler 43.

In some embodiments, the valve between the liquid cooling equipment and the cooling tower 80 can be a multi-port valve, with different ports of the multi-port valve connected to the cooling tower 80, the dry cooler 43, and the plate evaporator 41, respectively. The control device 44 can control the opening and closing of different ports of the multi-port valve to control the connection/disconnection between the liquid cooling equipment and the dry cooler 43 and the connection/disconnection between the liquid cooling equipment and the plate evaporator 41, and control the connection/disconnection between the liquid cooling equipment and the dry cooler 43.

In some embodiments, the valve between the liquid cooling equipment and the cooling tower 80 can be a solenoid valve. The control device 44 adjusts the flow rate of the thermal load entering the cooling tower 80 by controlling the opening degree of the solenoid valve, thereby adjusting the cooling efficiency.

In some embodiments, the control device 44 can adjust the flow rates of the thermal load entering any two of the plate evaporator 41, dry cooler 43, and cooling tower 80 by controlling the opening degree of the multi-port valve, thereby achieving regulation of the cooling efficiency.

In an embodiment, the cooling tower 80 may include a fan, and the cooling efficiency of the cooling tower 80 can be adjusted by controlling the operating frequency of the fan.

In an embodiment, the chiller unit 40 and the cooling tower 80 can be integrated in a container to make the structure of the cooling system 100 more compact.

It can be understood that in application scenarios where the temperature is excessively high, the cooling tower 80 can be used for heat exchange, thereby reducing cooling costs. After integrating the cooling tower 80 into the cooling system, the system can use the cooling tower 80 for heat exchange with the thermal load in high-temperature environments, use the dry cooler 43 for heat exchange with the thermal load in low-temperature environments, use the cooling water in the plate evaporator 41 for heat exchange with the thermal load in environments abundant with water resources, and use the refrigerant medium in the plate evaporator 41 for heat exchange with the thermal load in environments rich in power resources, enabling the cooling system 100 to be applicable in various application scenarios, meeting the diverse needs of users.

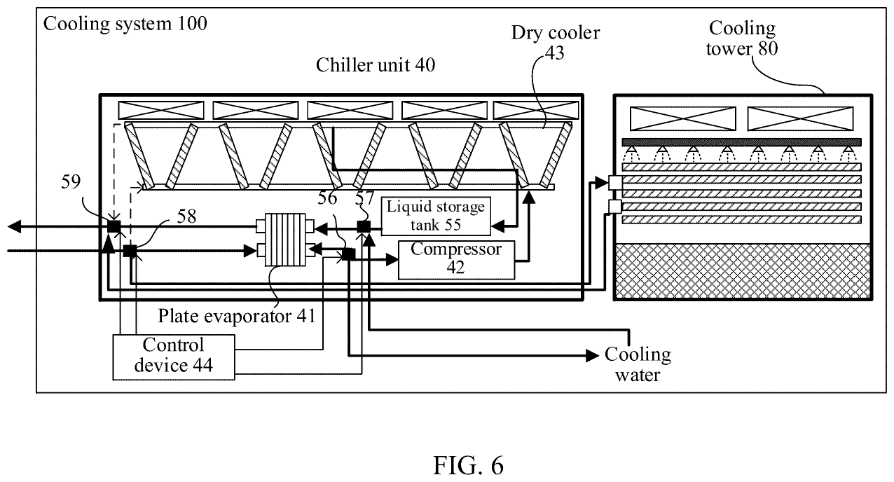

FIG. 6 is a schematic diagram of a sixth cooling structure of a cooling system provided by an embodiment of the present disclosure. Referring to FIG. 6, the liquid cooling equipment can be connected to the plate evaporator 41 of the chiller unit 40 via pipelines, connected to the dry cooler 43 of the chiller unit 40 via pipelines, and connected to the cooling tower 80 via pipelines.

In an embodiment, the water pump can input the thermal load of the liquid cooling equipment into the cooling tower 80 through the output port of the liquid cooling equipment. After exchanging heat within the cooling tower 80, the thermal load can be output to the input port of the liquid cooling equipment from the cooling tower 80 to be input into the liquid cooling system again.

In an embodiment, the chiller unit 40 may further include: a third valve 58 and a fourth valve 59. The output port of the liquid cooling equipment is connected to the first port of the third valve 58, and the first port of the third valve 58 is connect to the second port of the third valve 58. The second port of the third valve 58 is connected to the first input port of the plate evaporator 41. The first output port of the plate evaporator 41 is connected to the first port of the fourth valve 59, and the first port of the fourth valve 59 is connected to the second port of the fourth valve 59. The second port of the fourth valve 59 is connected to the input port of the liquid cooling equipment, forming a circuit between the liquid cooling equipment and the plate evaporator 41. The output port of the liquid cooling equipment is connected to the first port of the third valve 58, and the first port of the third valve 58 is connected to the third port of the third valve 58. The third port of the third valve 58 is connected to the dry cooler 43, the dry cooler 43 is connected to the third port of the fourth valve 59. The third port of the fourth valve 59 is connected to the second port of the fourth valve 59, and the second port of the fourth valve 59 is connected to the input port of the liquid cooling equipment, forming a circuit between the liquid cooling equipment and the dry cooler 43. The output port of the liquid cooling equipment is connected to the first port of the third valve 58, and the first port of the third valve 58 is connected to the fourth port of the third valve 58. The fourth port of the third valve 58 is connected to the cooling tower 80, the cooling tower 80 is connected to the fourth port of the fourth valve 59. The fourth port of the fourth valve 59 is connected to the second port of the fourth valve 59, and the second port of the fourth valve 59 is connected to the input port of the liquid cooling equipment, forming a circuit between the liquid cooling equipment and the cooling tower 80.

In an embodiment, the control device 44 controls the first port of the third valve 58 to be connected with the fourth port of the third valve 58 while controls the first port of the third valve 58 to be disconnected with the second and third ports of the third valve 58, and controls the second port of the fourth valve 59 to be connected with the fourth port of the fourth valve 59 while controls the second port of the fourth valve 59 to be disconnected with the first and third ports of the fourth valve 59, enabling the thermal load of the liquid cooling equipment to be input into the cooling tower 80 for exchanging heat. The thermal load is input into the cooling tower 80 through the output port of the liquid cooling equipment. After exchanging heat within the cooling tower 80, the thermal load can exit the cooling tower 80 and be input into the liquid cooling equipment again through the input port of the liquid cooling equipment.

It can be understood that when the control device 44 inputs the thermal load of the liquid cooling equipment into the cooling tower 80 for heat exchange, it can also control the thermal load to be input into the plate evaporator 41 and/or the dry cooler 43. When the control device 44 controls the thermal load of the liquid cooling equipment to be input into the plate evaporator 41 and/or the dry cooler 43, the connection/disconnection of the third valve 58 and the fourth valve 59 can refer to the descriptions in one or more of the aforementioned embodiments. For the sake of brevity in this specification, these details will not be repeated here.

In the embodiments of the present disclosure, the cooling system can achieve cooling under different application scenarios, thereby effectively reducing equipment costs and saving space.

After considering the description and putting the invention disclosed herein into practice, those skilled in the art will readily conceive of other embodiments of the present disclosure. The present disclosure aims to encompass any modifications, applications, or adaptive changes that adhere to the general principles of the present disclosure and incorporate common knowledge or conventional technical means in the present technical field that are not explicitly disclosed herein. The description and examples provided are to be regarded as illustrative only, and the true scope and spirit of the present disclosure are indicated by the following claims.

It should be understood that the present disclosure is not limited to the precise structure that has been described above and illustrated in the accompanying drawings, and that various modifications and changes can be made without departing from its scope. The scope of the present disclosure is solely defined by the appended claims.

What is claimed is:

1. A cooling system connected to a liquid cooling device, wherein the cooling system comprises:
a chiller unit comprising a plate evaporator, a compressor, and a dry cooler; wherein the plate evaporator, the compressor, and the dry cooler form a first medium circuit, a refrigerant medium is circulated in the first medium circuit, the plate evaporator and a cooling water source form a second medium circuit, and cooling water supplied by the cooling water source is circulated in the second medium circuit; and
a control device, configured to control connection of the first medium circuit and disconnection of the second medium circuit, wherein thermal load of the liquid cooling equipment exchanges heat with the refrigerant medium in the plate evaporator; or, configured to control disconnection of the first medium circuit and connection of the second medium circuit, wherein thermal load of the liquid cooling equipment exchanges heat with the cooling water in the plate evaporator.

2. The cooling system according to claim 1, wherein the control device is further configured to, control the connection of the first medium circuit and the disconnection of the second medium circuit when a power resource is sufficient; or, control the disconnection of the first medium circuit and the connection of the second medium circuit when the cooling water supplied by the cooling water source is sufficient.

3. The cooling system according to claim 1, wherein in the first medium circuit, the refrigerant medium is input into the plate evaporator to exchange the heat with the thermal load, and the heat-exchanged refrigerant medium sequentially passes through the compressor for volume compression and the dry cooler for cooling and is input into the plate evaporator again;
in the second medium circuit, the cooling water from the cooling water source is input into the plate evaporator to exchange heat with the thermal load, the heat-exchanged cooling water is output to the cooling water source.

4. The cooling system according to claim 1, wherein the thermal load is output to the plate evaporator from the liquid cooling equipment, and exchanges heat within the plate evaporator, and the heat-exchanged thermal load is returned to the liquid cooling equipment.

5. The cooling system according to claim 4, wherein the chiller unit further comprises a water tank; the heat-exchanged thermal load is passed through the water tank for secondary heat exchange, and is returned to the liquid cooling equipment.

6. The cooling system according to claim 1, wherein the chiller unit further comprises: a liquid storage tank connected to the plate evaporator, and the liquid storage tank stores the refrigerant medium;
the control device is further configured to control the liquid storage tank to output the refrigerant medium to the plate evaporator when the first medium circuit is connected; or, to control the liquid storage tank to stop outputting the refrigerant medium to the plate evaporator when the first medium circuit is disconnected.

7. The cooling system according to claim 1, wherein the chiller unit further comprises: a power supply module connected to the compressor;
the control device is further configured to control the power supply module to supply power to the compressor when the first medium circuit is connected.

8. The cooling system according to claim 1, wherein the thermal load is output to the dry cooler from the liquid cooling equipment and exchanges heat within the dry cooler, and the heat-exchanged thermal load is returned to the liquid cooling equipment.

9. The cooling system according to claim 1, wherein the cooling system further comprises a cooling tower, the cooling tower comprises a spray assembly, the thermal load is output to the cooling tower from the liquid cooling equipment, and exchanges heat within the cooling tower through spraying a cooling medium by the spray assembly, and the heat-exchanged thermal load is returned to the liquid cooling equipment.

10. The cooling system according to claim 4, wherein the control device is further configured to perform at least one of the following:
controlling the thermal load to be input from the liquid cooling equipment into the plate evaporator for the heat exchange;
controlling the thermal load to be input from the liquid cooling equipment into the dry cooler for the heat exchange;
controlling the thermal load to be input from the liquid cooling equipment into a cooling tower for the heat exchange.

11. The cooling system according to claim 5, wherein the control device is further configured to perform at least one of the following:
controlling the thermal load to be input from the liquid cooling equipment into the plate evaporator for the heat exchange;
controlling the thermal load to be input from the liquid cooling equipment into the dry cooler for the heat exchange;
controlling the thermal load to be input from the liquid cooling equipment into a cooling tower for the heat exchange.

12. The cooling system according to claim 6, wherein the control device is further configured to perform at least one of the following:
controlling the thermal load to be input from the liquid cooling equipment into the plate evaporator for the heat exchange;
controlling the thermal load to be input from the liquid cooling equipment into the dry cooler for the heat exchange;
controlling the thermal load to be input from the liquid cooling equipment into a cooling tower for the heat exchange.

13. The cooling system according to claim 7, wherein the control device is further configured to perform at least one of the following:
controlling the thermal load to be input from the liquid cooling equipment into the plate evaporator for the heat exchange;
controlling the thermal load to be input from the liquid cooling equipment into the dry cooler for the heat exchange;
controlling the thermal load to be input from the liquid cooling equipment into a cooling tower for the heat exchange.

14. The cooling system according to claim 8, wherein the control device is further configured to perform at least one of the following:
controlling the thermal load to be input from the liquid cooling equipment into the plate evaporator for the heat exchange;
controlling the thermal load to be input from the liquid cooling equipment into the dry cooler for the heat exchange;
controlling the thermal load to be input from the liquid cooling equipment into a cooling tower for the heat exchange.

15. The cooling system according to claim 9, wherein the control device is further configured to perform at least one of the following:
controlling the thermal load to be input from the liquid cooling equipment into the plate evaporator for the heat exchange;
controlling the thermal load to be input from the liquid cooling equipment into the dry cooler for the heat exchange;
controlling the thermal load to be input from the liquid cooling equipment into the cooling tower for the heat exchange.
